(19) United States
(12) Patent Application Publication
(10) Pub. No.: US 2006/0223231 A1
(43) Pub. Date: Oct. 5, 2006

(54) Packing method for electronic components

(75) Inventors: Ichiro Koiwa, Minato-ku (JP); Mitsuhiro Watanabe, Yokosuka-shi (JP)

Correspondence Address: ROTHWELL, FIGG, ERNST & MANBECK, P.C., 1425 K STREET, N.W., SUITE 800, WASHINGTON, DC, 20005, US

(73) Assignees: Oki Electric Industry Co., Ltd., Minato-ku (JP); Multi Inc., Yokosuka-shi (JP)

(21) Appl. No.: 11/397,711

(22) Filed: Apr. 5, 2006

(30) Foreign Application Priority Data
Apr. 5, 2005 (JP) JP2005-109079

(51) Int. Cl. H01L 21/00

(52) U.S. Cl. 438/108

(57) ABSTRACT

A packaging method which makes possible firm connection of electronic components having bump areas and a wiring board having a pad electrode portion with secure electrical conduction is to be provided. To achieve this object, according to the packaging method which makes possible firm connection of electronic components having bump areas and a wiring board having a pad electrode portion with secure electrical conduction, the surface of the pad electrode portion of the wiring board has a roughened surface of 0.1 μm (Rzjis) or more, a layer of thermosetting adhesive resin in a semi-cured stage is provided over the roughened surface of the pad electrode portion, the bump areas of electronic components and the pad electrode portion of the wiring board are placed one over the other to be arranged opposite each other, and crimped under pressure and heating. The roughened surface of the pad electrode portion of the wiring board is obtained by etching the pad electrodes or otherwise.

### BACKGROUND OF THE INVENTION

1. Field of the Invention

The present invention relates to a packaging method for connecting electronic components having bump areas and a wiring board having a pad electrode portion, and more particularly to a packaging method suitable for packaging on a wiring board electronic components having many electrodes, such as flip chip components.

2. Description of the Related Art

Today's electrical products and electrical equipment not only are required to be multifunctional but also have to meet endless requirements for downsizing, with a consequence that electrical products and electrical equipment are reduced in weight, thickness, length and overall size. Therefore, printed wiring boards and electronic components mounted thereon, both accommodated within such products or equipment, are required to be highly functional within the limited accommodation space.

One of the qualitative features required in the context of this tendency is the way of mounting compact and high-performance chip components on the downsized wiring board. In other words, it is a question of how to ensure reliable connection between the wiring board and packaged electronic components. If techniques for this packaging are inadequate, however excellent in quality the wiring board and the electronic components including chips may be by themselves, not only electrical products and electrical equipment consisting of them cannot be expected to remain useful for long periods but also their quality cannot be stabilized, and eventually consumers' trust might be betrayed.

Therefore, various research attempts have been made of techniques for packaging electronic components on wiring boards, resulting in the proposition of many different packaging techniques. In Patent Document 1, for instance, it is proposed to use means of joining electrode circuits with an anisotropic conductive film (ACF) as a technique for packaging electronic components, such as semiconductor chips, on a wiring board. However, conductive particles are dispersed within an ACF, the quantity of conductive particles usually fluctuates from one location to another if the state of this dispersion is uneven. And this local fluctuation of the conductive particles obstructs smooth joining of the bump areas of electronic components or the like and the pad area of the wiring board when the components are crimped under heating for packaging, sometimes leading to a peeled-off state. When an ACF is used, conductive particles which do not contribute to inter-layer conduction also remain between circuits, inviting a drop in insulating performance. Such a peel-off phenomenon prevents high reliability of electrical connection from being achieved, and the resultant drop in insulating performance would shorten the useful life of the product and considerably reduce the yield of products.

An attempt to solve this problem is described in Patent Document 2. According to the packaging method proposed therein, with an eye to prevent conductive particles from escaping through the joints between bumps on the chip electrodes and electrodes on the substrate at the time of packaging electronic components including bare chips by a fine-pitch flip chip process, hard conductive particles of nickel or the like are transferred or attached only to the bump tips in advance, followed by adhering the bumps to the substrate electrodes, or sealing the gaps between them, with an insulative resin mainly consisting epoxy resin and hardening agent, thereby to prevent conductive particles from escaping. Then, electrical coupling between the electrodes is secured and electrical insulation between adjoining terminals is improved by eliminating unnecessary conductive particles between the adjoining terminals, thereby to make possible highly reliable packaging of electronic components.

Thus, according to the packaging method disclosed in Patent Document 2, in order to secure electrical conduction through the joints between the bumps on the chip electrodes and the electrodes on the substrate, fine conductive particles of hard metal, such as nickel, are stuck onto the joint surfaces of bumps with conductive adhesive applied to the bumps and embedded in an engaged state between the bumps 12 and electrodes on the substrate by the heating at the time of thermal crimping.

[Patent Document 1] Japanese Patent Laid-Open No. 8-222599 (claim 3)

[Patent Document 2] Japanese Patent Laid-Open No. 11-135925 (claim 1)

### SUMMARY OF THE INVENTION

However, the packaging method disclosed in Patent Document 2 involves the following problems. Whereas fine conductive particles of hard metal, such as nickel, have to be stuck onto the joint surfaces of bumps with conductive adhesive applied to the bumps on the chip electrodes, the conductive particles once stuck to the bumps on the chip electrodes may come off, depending on the way of subsequent handling.

Even if the conductive particles stuck to the bumps on the chip electrodes do not come off, if they are not stuck tight enough, the pressure at the time of thermal crimping may free them in the insulative layer between circuits, inviting a drop in the insulating performance of the insulative layer.

Because of these problems, the market has been looking for a packaging method by which electronic components having bump areas and a wiring board having a pad electrode portion can be connected with secure electrical conduction and these problems can be solved.

The fundamental concept of a packaging method for electronic components according to the present invention is a packaging method for connecting electronic components having bump areas and a wiring board having a pad electrode portion while securing electrical conduction between them, wherein; the surface of said pad electrode portion of the wiring board is provided with a roughened surface of 0.1 μm (Rzjis) or more, comprising the steps of: providing a layer of thermosetting adhesive resin in a semi-cured stage over the roughened surface of the pad electrode portion; placing the bump areas of said electronic components and the pad electrode portion of the wiring board one over the other to be arranged opposite to each other, and crimping under pressure and heating the bump areas of said electronic components and the pad electrode portion of the wiring board.

In the packaging method for electronic components according to the invention, it is preferable for the roughened surface of the pad electrode portion of the wiring board to be obtained by etching pad electrodes.

Further in the packaging method for electronic components according to the invention, it is also preferable for the roughened surface of the pad electrode portion of the wiring board to have a prominent shape electrodeposited by an electro plating or a electro-less plating.

In the packaging method for electronic components according to the invention, it is preferable for the difference in Vickers' hardness between the metal component constituting the bump areas of the electronic components and the metal component constituting the pad electrode portion of the wiring board to be 15 Hv or more.

In the packaging method for electronic components according to the invention, it is preferable for the electronic components to be flip chip components.

In the packaging method for electronic components according to the invention, it is preferable for each of the flip chip component to be a flip chip component with a passivation layer on its electrode surface in which a contact hole is opened only in the position matching a bump area and a conductive material is embedded within the contact hole.

Also, the electronic component may be a wiring board having bump areas.

It is preferable for the wiring board having a pad electrode portion to be a wiring board whose pad electrode portion is embedded in the base material of the wiring board and the surface of the pad electrode portion and for the reference surface of the wiring board to be substantially equal in height.

In the packaging method for electronic components according to the invention, it is also preferable for the material of the layer of thermosetting adhesive resin to be epoxy functional thermosetting resin, phenol functional thermosetting resin, polyimide functional thermosetting resin or urethane functional thermosetting resin.

The layer of thermosetting adhesive resin may contain anisotropic conductive particles.

It is preferable for the resin flow of the layer of thermosetting adhesive resin is 15% to 50%.

The packaging method for electronic components according to the present invention is a packaging method for connecting electronic components having bump areas and a wiring board having a pad electrode portion with secure electrical conduction, wherein a roughened surface is formed by sticking fine metal grains onto the surface of the pad electrode portion of the wiring board by etching or electrolysis, whereby the particles and the like constituting the roughened surface would not come off the pad surface. Therefore, the prominent shape after the roughing of the pad surface would not come off, resulting in greater handling ease. Nor do the stubs having contributed to the roughing do not come free within the insulating layer after the crimping under heating, making it possible to secure satisfactory electrical insulation of the insulating layer.

By the packaging method for electronic components according to the invention, moreover, as the prominent shape of the roughened surface formed over the pad surface cuts into the electrode of the electronic component and exerts an anchoring effect, sufficient electrical conduction can be secured without having to use conductive particles such as the ones used in the anisotropic conductive film. Furthermore, for roughing the pad electrode portion of the wiring board, it is possible to use a common etching line or plating line, but no particular capital investment would be required, making it possible to adopt a production method excelling in economic performance as well.

### BRIEF DESCRIPTION OF THE DRAWINGS

FIGS. 1(A) to 1(B-2) schematically illustrate the flow of a packaging method according to the present invention in a sectional direction;

FIGS. 2(c) to 2(E) also schematically illustrate the flow of a packaging method according to the present invention in a sectional direction;

FIGS. 3(A) and 3(B) schematically illustrate in a sectional view the roughed state when a clad structure is used for the pad area of the wiring board;

FIGS. 4(A) and 4(B) schematically illustrate in a sectional view the flow of forming a passivation layer over the electrode surface of a flip chip component;

FIGS. 5(C) and 5(D) also schematically illustrate in a sectional view the flow of forming a passivation layer over the electrode surface of a flip chip component;

FIG. 6(E) also schematically illustrates in a sectional view the flow of forming a passivation layer over the electrode surface of a flip chip component;

FIGS. 7(A) to 7(B-2) are schematic diagrams illustrating a packaging flow using a wiring board of a specific shape usable by the packaging method according to the invention;

FIGS. 8(C) and 8(D) are schematic diagrams illustrating a packaging flow using a wiring board of a specific shape usable by the packaging method according to the invention;

FIG. 9(E) is schematic diagram illustrating a packaging flow using a wiring board of a specific shape usable by the packaging method according to the invention;

FIGS. 10(A) and 10(B) are schematic diagrams illustrating a packaging flow using a wiring board of a specific shape usable by the packaging method according to the invention;

FIGS. 11(C) and 11(D) are schematic diagrams illustrating a packaging flow using a wiring board of a specific shape usable by the packaging method according to the invention;

FIGS. 12(E) and 12(F) are schematic diagrams illustrating a packaging flow using a wiring board of a specific shape usable by the packaging method according to the invention;

FIGS. 13(G) and 13(H) are schematic diagrams illustrating a packaging flow using a wiring board of a specific shape usable by the packaging method according to the invention; and

FIG. 14(I) is a schematic diagram illustrating a packaging flow using a wiring board of a specific shape usable by the packaging method according to the invention.

### DETAILED DESCRIPTION OF THE PREFERRED EMBODIMENTS

The fundamental concept of the packaging method for electronic components according to the present invention is, as stated above, to connect electronic components having bump areas and a wiring board having a pad electrode portion with secure electrical conduction, whereby the surface of the pad electrode portion of the wiring board has a roughened surface of 0.1 μm (Rzjis) or more, a layer of thermosetting adhesive resin in a semi-cured stage is provided over the roughened surface of the pad electrode portion, the bump areas of electronic components and the pad electrode portion of the wiring board are placed one over the other to be arranged opposite to each other, and crimped under pressure and heating.

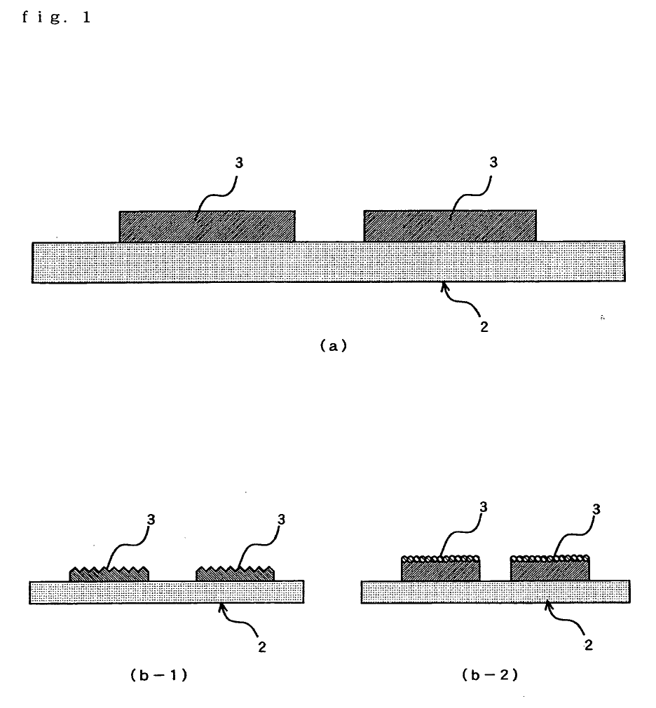

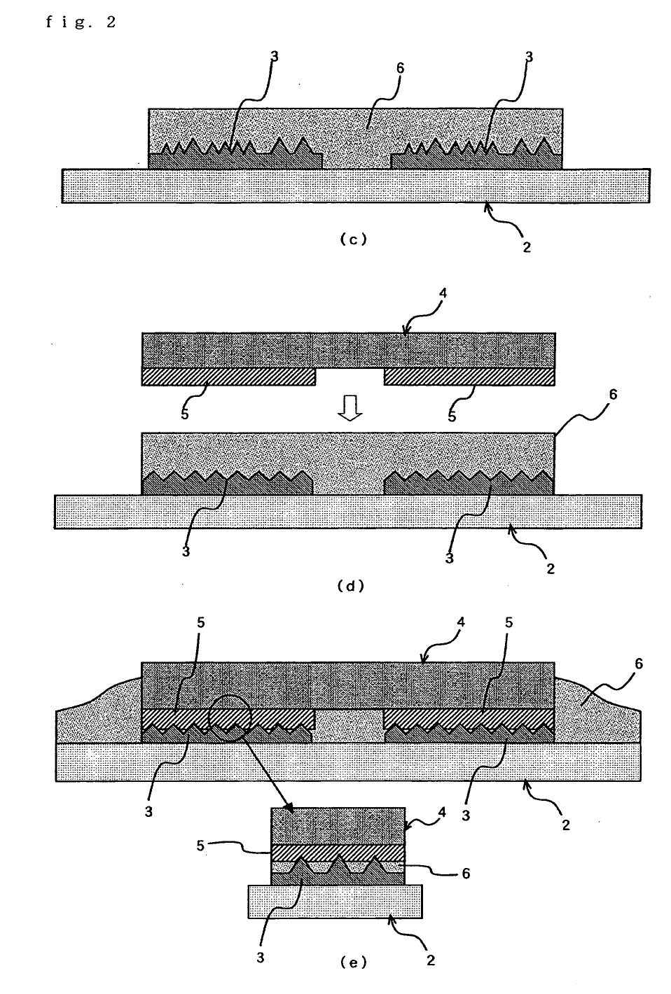

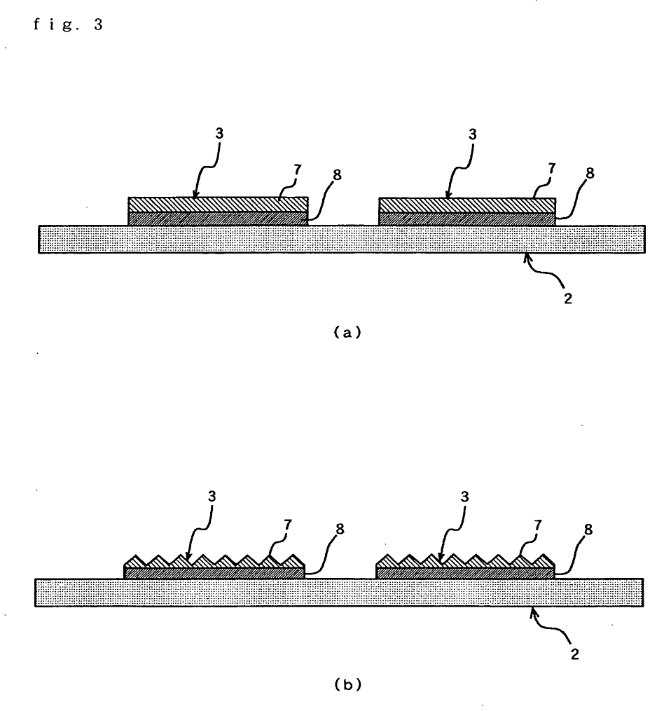

The flow of this packaging method will be described with reference to schematic diagrams of FIGS. 1(A) to 1(B-2) and FIGS. 2(C) to 2(E) which illustrate it in a sectional direction. The schematic sections in the drawings are shown merely to facilitate understanding, and the thickness, size and other factors of the portions therein do not reflect the actual thickness, size or other pertinent factor.

First, the overall flow of the surface packaging method according to the invention will be described. A wiring board 2 provided with a pad electrode portion 3 shown in FIG. 1(A) is made ready for use. By the packaging method for electronic components according to the invention, the surfaces of these pad electrode portions 3 of the wiring board 2 are roughed either as shown in FIG. 1(B-1) or as shown in FIG. 1(B-2). After that, as shown in FIG. 2(C) (in the following illustrations in FIGS. 2(D) and 2(E), the use of roughing shown in FIG. 1(B-1) is supposed), a thermosetting adhesive resin layer 6 is provided over that roughened surface as the adhesive layer to connect the pad electrode portions 3 of the wiring board 2 and bump areas 5 of an electronic component 4. Then, as shown in FIG. 2(D), the electronic component 4 is mounted over the surface of this thermosetting adhesive resin layer 6. In order to re-fluidize and harden the thermosetting resin layer 6 in a semi-cured stage, it is heated, pressurized and stuck to form a surface-packaged substrate 1 as shown in FIG. 2(E). Specific elements required for this process will be described below in the sequence of their coming up.

Wiring board: The wiring board 2 in this context, provided with the pad electrode portion 3 shown in FIG. 1(A), is described as a concept covering a printed wiring board and a silicon substrate. The pad electrode portion 3 on the surface of this wiring board 2 is usually composed of copper or a copper alloy, excellent in electrical conductivity. The copper alloy here may be selected out of copper alloys C1000 through C2000 under JIS H 3100, brass, free cutting brass, tin brass, admiralty brass, naval bronze, aluminum bronze, white copper and so forth. What is to constitute the wiring board 2 here is supposed to be any kind of wiring board such as a so-called printed wiring board, a matrix substrate for chip component production and a glass substrate.

By the packaging method for electronic components according to the invention, by roughing the pad electrode portions 3 of the wiring board 2, the surface of each pad electrode portion 3 is made a roughened surface 4. This roughened surface is formed by either machining the surface of the pad electrode portion 3 in a certain way as shown in FIG. 1(B-1) to create a rugged shape or a prominent shape (both are collectively referred to as a “prominent shape” in the context of the invention) or by sticking fine metal grains onto the surface of the pad electrode portion 3 as shown in FIG. 1(B-2) by an electro plating or a electro-less plating to create the prominent shape. The prominent shape of this roughened surface, when it is crimped under heating onto the bump area of an electronic component, cuts through the surface of the bump area of the electronic component into its inside, serves to firmly connect by its anchoring effect and thereby performs the role of securing electrical conduction, resulting in a dramatic improvement in the reliability of electrical connection between the layers.

In roughing the surface as shown in FIG. 1(B-1), it is preferable to use as the roughened surface of the pad electrode portion of the wiring board what is obtained by etching pad electrodes. A roughened surface obtained by etching, since it does not involve posterior sticking of conductive particles with a conductive adhesive as described in Patent Document 2, is free from the phenomenon in which the conductive particles come off after the formation of the roughened surface, and accordingly the handling of the wiring board after the roughing process is made easier. Moreover, when it is crimped onto the bump area of the electronic component under heating, no conductive particle would become free and move into the insulating resin layer, and correspondingly the reliability of the electrical insulation of the insulating layer is enhanced. It is preferable for the height of stubs of the prominent shape then to be 0.1 μm or more as expressed in an Rzjis value. If it is less than 0.1 μm, the thermosetting resin is more likely to remain between the layers, and the level of cutting into the bump area of the electronic component will not be deep enough to improve the reliability of connection. The upper limit of the stub height of the prominent shape is not prescribed in particular, because limit can vary with the electrode thickness of the electronic component. However, even if the stub height of the prominent shape surpasses 3.0 μm, there will be no extra contribution to the reliability of connection, and only the machining cost will increase. Therefore, the preferable stub height range for securing reliable connection with due consideration for economic efficiency in the mass production process is 0.3 μm to 2.5 μm, more preferably 0.3 μm to 2.0 μm.

Considering that the prominent shape of this roughened surface here is intended to cut through the surface of the bump area of the electronic component into its inside when the area is to be crimped under heating, it is desirable to take into account the difference in hardness as a difference in the physical properties of the material of the prominent shape of the bump area. The reason is that, if the prominent shape is harder than the material constituting the bump area, it will be easier to make the prominent shape cut through the surface of the bump area of the electronic component into its inside.

Then, by differentiating the constituent material of the bump area of the electronic component and that of the pad area of the wiring board, more solid connection can be achieved in crimping under heating. Supposing that the bump area of the electronic component is formed of a copper foil or copper plating for instance, the range of Vickers' hardness (Hv) will usually be 90 to 120. Then, a harder material than the constituent material of the bump area of the electronic component by 15 or more in Vickers' hardness count is used as the constituent material of the pad area of the wiring board. A difference in Vickers' hardness by 15 or more would enable the prominent shape to easily cut through the bump area without suffering plastic deformation. This hardness difference can be readily achieved by using pure copper as the constituent material of the bump area of the electronic component and a copper alloy as the constituent material of the pad area of the wiring board. Or even if the constituent material of the bump area of the electronic component and that of the pad area of the wiring board are both pure copper, the two elements can be easily differentiated by varying the conditions of their fabrication, electrolysis and plating, and there is no particular limitation to their fabrication methods. To add, Vickers' hardness as referred to in the description of the present invention is measured with a diamond pyramid (136° in vertical angle) at a load of 50 g. When any part of 50 μm or less in thickness was to be measured, a measuring sample of 50 μm or more in thickness was adjusted and its Vickers' hardness was measured.

Therefore, it is preferable to form the whole pad area of the wiring board of a harder material than the constituent material of the bump area of the electronic component. It is also preferable to use for the configuration of the pad area of the wiring board a clad form comprising a hard metal layer 7, a usual copper layer 8 and the like as shown in FIG. 3(A). In this case, the hard metal layer 7 is etched to form a prominent shape 9 as shown in FIG. 3(B).

When roughing is to be processed as shown in FIG. 1(B-1), it is preferable for the roughened surface of the pad electrode portion of the wiring board to have a prominent shape electrodeposited by electrolysis. The advantage of using electrolysis is that the material only of the prominent shape can be altered to create the aforementioned hardness difference from the constituent material of the bump area of the electronic component. Further by using the fabricating method described below, it is made possible to firmly stick the pad electrode portion of the wiring board.

Where the prominent shape is to be shaped by electrolysis, fine metal grains are stuck to the pad electrode portion under burnt plating conditions by using an electrolyte for depositing metal components. Though there is no particular limitation to the burnt plating conditions then, it is sufficient to take into account the square measure of the pad electrode portion and other relevant factors to be able to stick fine metal particles of an appropriate size. The tendency is that the finer the grain size of the metal particles, the firmer their sticking to the surface of the pad electrode portion.

If some of the fine metal grains stuck to the pad electrode portion under the burnt plating conditions stated above are found coming off when they are left as they are, it is desirable to fix the stuck fine metal grains by performing uniform plating by short-period electrolysis under smooth plating conditions by using an electrolyte for depositing metal components.

Layer of thermosetting adhesive resin: When the roughened surface is formed on the pad electrode portion of the wiring board as described above, the thermosetting adhesive resin layer 6 is provided over the roughened surface as the adhesive layer for connecting the pad electrode portions 3 of the wiring board 2 and the bump areas 5 of the electronic component 4 as shown in FIG. 2(C).

The formation of this thermosetting resin layer may be accomplished either by applying and drying resin varnish to make it a half-hardened resin layer or by sticking a half-hardened resin film machined into a film shape in advance. Any electronic material that can be used for the formation of an insulating resin layer can be used for the formation of this thermosetting resin layer. Therefore, it is preferable to use a configuration having epoxy functional thermosetting resin, phenol functional thermosetting resin, polyimide functional thermosetting resin or urethane functional thermosetting resin as its resin component.

It is preferable for the thickness of this thermosetting resin layer to be 3 μm to 5 μm in a semi-cured stage from the tip of the prominent shape on the roughed surface of the pad electrode portion. If it is less than 3 μm, crimping under heating will give no sufficient joining strength, making it difficult to secure the minimum required resin flow. Resin cannot be satisfactorily embedded in other gaps, making it impossible to adequately package the electronic components over the wiring board. Or if it is more than 5 μm, the quantity of the resin flow at the time of crimping under heating will become greater than required, making it impossible to package the components securely in a compact area.

By adopting the packaging method according to the invention, the pad electrode portion of the wiring board and the bump areas of the electronic components can be securely connected without having conductive particles, such as those used in an anisotropic conductive film, intervene between them. However, this means nothing more than the absence of need for conductive particles intervening in the thermosetting resin layer, but it is permissible to have such conductive particles intervene therein. In the packaging method according to the invention, if conductive particles are let intervene in the thermosetting resin layer, the conductive particles will be bitten between the roughed pad electrode portion of the wiring board and the bump areas of electronic components, resulting in a higher level of connection reliability than a usual anisotropic conductive film would be provided. Although there is no particular limitation to the kind of conductive particles to be used then, especially where conductive particles have a plastic coat layer, as the plastic coat layer of the conductive particles is efficiently cleaved between the pad electrode portion and the bump areas by the prominent shape formed by the roughing of the pad electrode portion of the wiring board, conductively can be securely obtained.

Sticking together of the electronic components and the wiring board: Next, as shown in FIG. 2(D), the electronic components are mounted over the surface of this thermosetting adhesive resin layer 6. Then, to re-fluidize the thermosetting resin layer 6 in the semi-cured stage and harden it, they are stuck under heating and pressure as shown in FIG. 2(E). There is no particular limitation to the heating conditions and the pressurizing conditions then, but the optimal conditions to permit most suitable sticking can be selected as appropriate for the type of the resin to be used and the strengths and other factors of the electronic components and the wiring board to be stuck together.

The characteristics required for the thermosetting adhesive resin layer 6 then include the resin flow at the time the resin is re-fluidized. In the packaging method according to the invention, it is preferable to use a thermosetting resin whose resin flow is within a range of 15% to 50%. In the context of the invention, the resin flow is determined by the value measured in conformity with MIL-P-13949G of the MIL standards. Thus, a sample of a resin composition for use in the thermosetting resin layer to be used by the surface packaging method according to the invention for measuring the resin flow, provided with a half-hardened resin layer of 80 μm in thickness on one surface of a metal foil, was prepared. This sample was stuck under the conditions of 171° C. in pressing temperature, 14 kgf/cm² in pressure and 10 minutes in pressing duration, and calculation was made by an equation of resin flow (%)=[weight of effluent resin] ([pre-pressing weight of sample]−[post-pressing weight of sample])×100.

In the packaging method according to the invention, if the resin flow is less than 15%, even if the thickness of the thermosetting resin layer is increased in crimping under heating, it will be difficult to secure the minimum required resin flow, making it difficult to achieve effective joining and to satisfactorily embed resin in other gaps. Or if the resin flow surpasses 50%, the resin flow under heating and pressure will become too great, deviations on the joining mold surface apt to occur if the pressure rises fast, and resin may be more likely to flow beyond the area occupied by the electronic components, which are packaged components. Considering the mass production stability of the process, it is more preferable to keep the resin flow in a range of 18% to 40%.

Usable electronic components: There is no particular limitation to electronic components that can be packaged in the wiring board by the surface packaging method according to the invention. Thus, the technical idea underlying the surface packaging method according to the invention is dependent on the shapes and other factors of the wiring board and of the electrodes of the electronic components to be packaged therein and, as long as the shape requirement is satisfied, any electronic component can be packaged. Therefore, it is preferable to use flip chip components or a printed wiring board among such electronic components, because they are superior in shape in terms of the application of the surface packaging method according to the invention. Nor is there any particular limitation regarding the constituent material of the bump areas of the electronic components. It is possible to use as desired copper, a copper alloy, gold, aluminum, solder or the like for instance. One can be appropriately selected out of these alternatives with do consideration for the hardness difference from the material constituting the pad area of the wiring board.

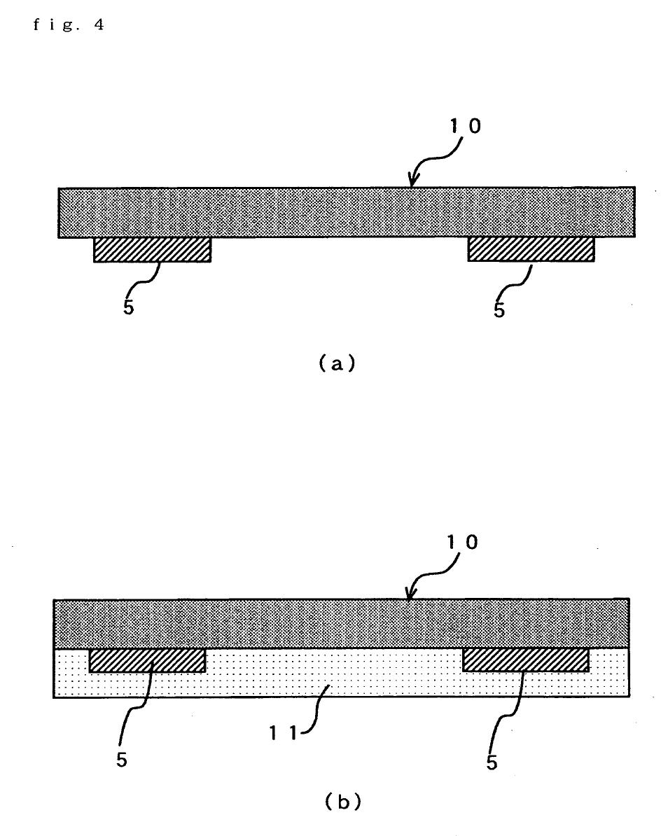

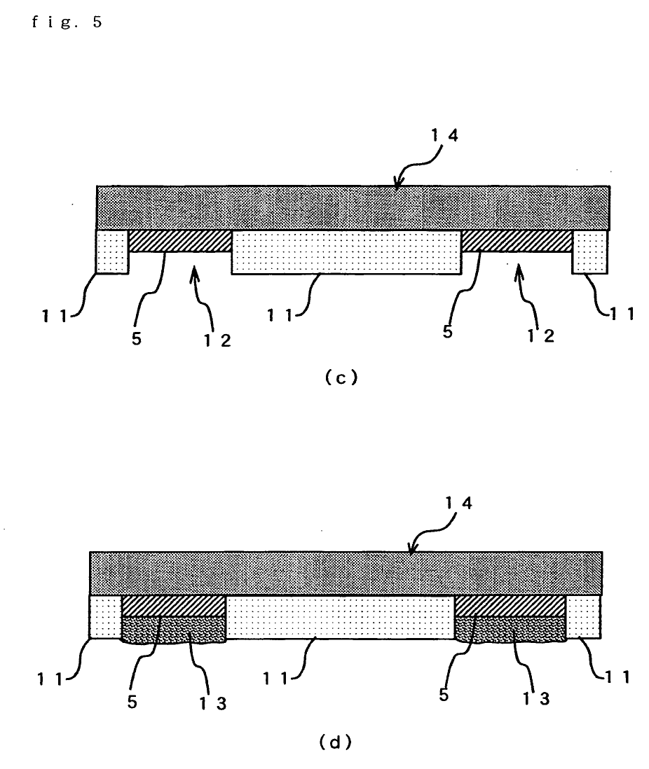

Among others, the flip chip components should preferably be passivation layer-equipped flip chip components, whose electrode surface is provided with a passivation layer in which a contact hole is opened only in the position matching a bump area and a conductive material is embedded within the contact hole. A method of fabricating such a passivation layer-equipped flip chip component will be described below with reference to FIG. 4 and FIG. 5.

As shown in FIG. 4(A), a usual flip chip component 10 is made available for use. Then, as shown in FIG. 4(B), a passivation layer 11 is formed over the electrode surface of the flip chip component 10. This passivation layer, which is a silicon nitride film formed by chemical vapor deposition (CVD), contributes to enhancing electrical insulating performance, and is intended to protect the electrode surface of the flip chip component 10. This passivation layer is formed to be thicker than the bump area of the flip chip component by 0.5 μm to 1 μm.

Next, as shown in FIG. 5(C), openings are formed in positions matching the bump areas 3 of the passivation layer 10 that has been formed. These openings can be formed by either photolithography or dry etching or by both, each according to its prescribed formula. These openings are called contact holes 12.

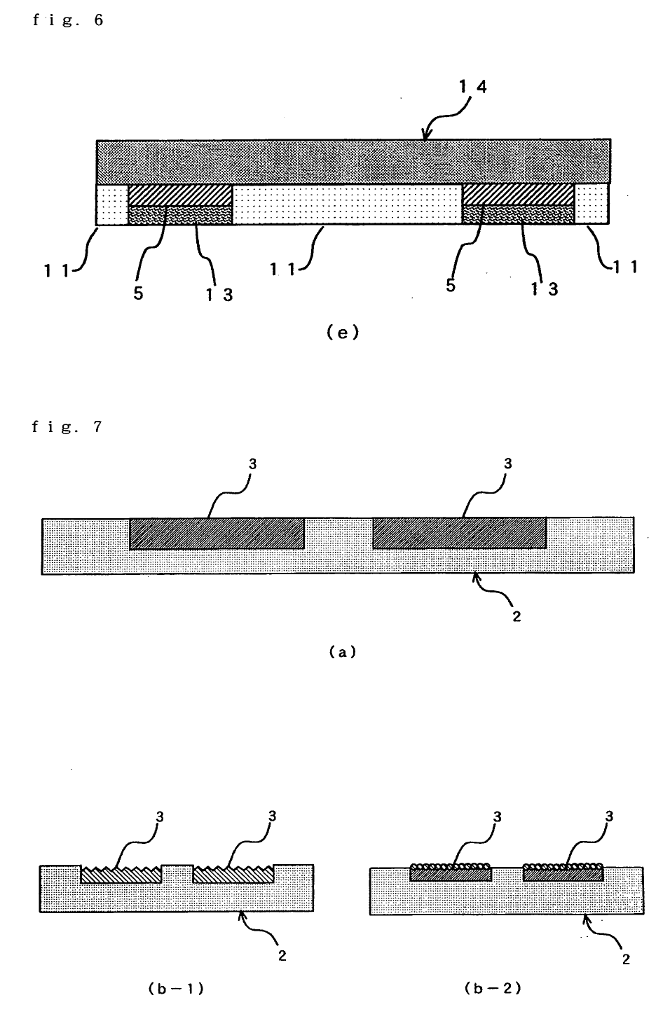

Then, each of the contact holes 12 formed as shown in FIG. 5(D) is filled with a conductive substance 13, such as conductive paste (silver paste or copper paste), cream solder or the like. In this filling process, if it is tried to completely fill the contact holes 12 with the conductive substance 13 by screen printing or otherwise, it will overflow the contact holes 12 to make it impossible to keep the surface smooth. Therefore, a passivation layer-equipped flip chip component 14 shown in FIG. 6(E) is obtained by grinding the surface. When conductive paste is used, as metal powder to be contained therein, silver particles, copper particles, nickel particles, tin particles or a mixture thereof can be selectively used. While the shape of the powder grains may be either spherical or flat, powder with an average primary grain size in the nm order and as free from aggregation as possible should be used because the performance to fill the contact holes improves where the grain size is smaller and the grains are more dispersive.

The parts in which conductive paste, cream solder or the like is embedded inside the contact holes are greater in hardness difference from the pad area of the wiring board, and the prominent shape of the pad area can more readily cut into, making it easier to secure electrical conduction.

It is also possible to use as the electronic component a wiring board having bump areas. Thus, the wiring board in the context of the present invention is stated as a concept covering a silicon substrate, printed wiring board and the like. Out of these possibilities, a case in which a printed wiring board having a pad area as a wiring board (hereinafter to be referred to as “motherboard” for the convenience of description) is used in the packaging method according to the invention will be considered below. When a small printed wiring board is mounted over the surface of the motherboard and its joining is attempted, the above-stated technical idea can be applied.

Thus the bump area of the small printed wiring board is joined to the pad area of the surface of the motherboard via a thermosetting resin layer. On this occasion, the aforementioned prominent shape is formed over the surface of the pad area. The pad area of the surface of the motherboard usually has a double-layered structure of a copper foil layer and a plated copper layer. The reason is that the motherboard is caused to constitute a circuit shape including the pad area by forming holes for inter-layer communication, such as through holes and via holes, in the copper foil layer provided over the surface of the insulating layer, plating with copper all over to secure electrical conduction between layers, and then etching, with an etching resist pattern being formed after that on each of the two surfaces. After that, etching resist formation is again carried out elsewhere than the pad area, and the roughed surface is formed by sticking fine metal grains only to the surface of the pad area or roughing the surface by etching. Then, by making the copper plating layer no harder than common copper, it is made easier to secure a sufficient hardness difference between the pad area of the motherboard and the bump areas of the small printed wiring board as described above. It is also permissible to provide the pad area, after the roughing, with an auxiliary layer to facilitate bonding, such as an Al—Cu alloy layer, Al—Cu—Si alloy layer, Ni layer or Au layer. By packaging and mounting a small printed wiring board over the surface of the motherboard as described above, it is made possible to adopt a three-dimensional wiring board structure and to fabricate a printed wiring board with a substantially increased number of layers in a small area. Moreover, it is also possible to obtain the inter-layer communication part formed by joining the pad area of the motherboard and the bump areas of the small printed wiring board as a thick conductor layer, and it is made easier to use it as a power supply circuit between layers.

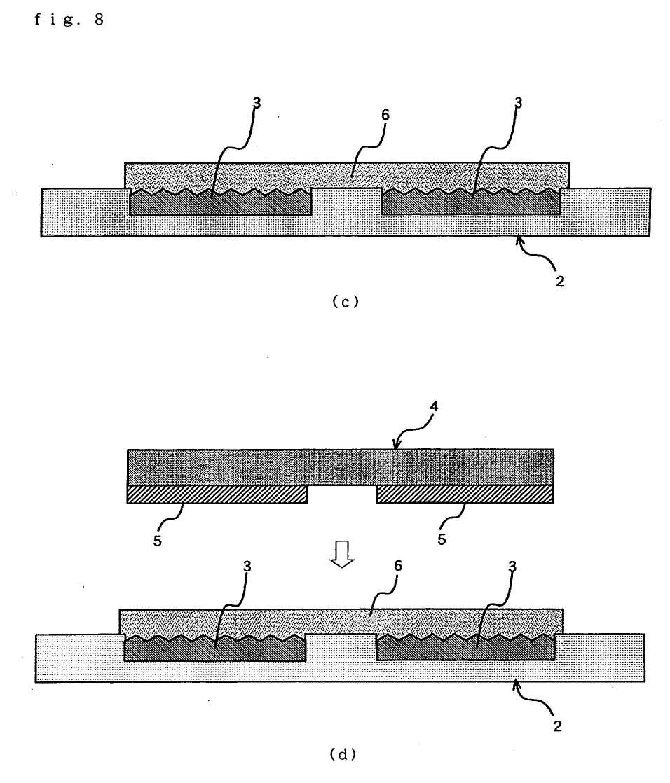

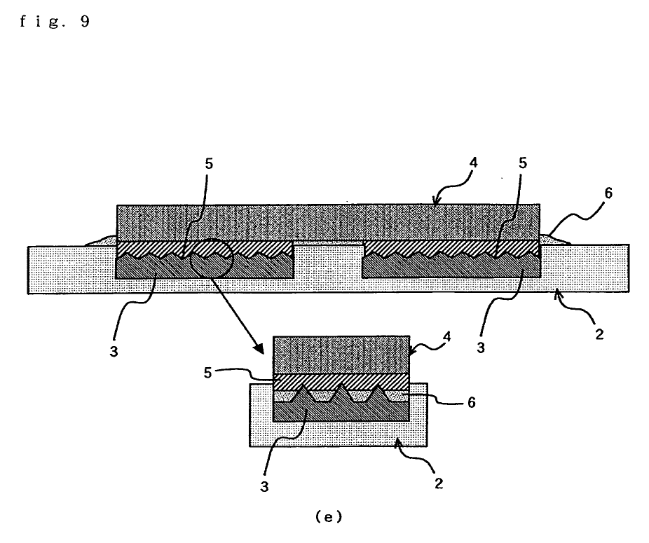

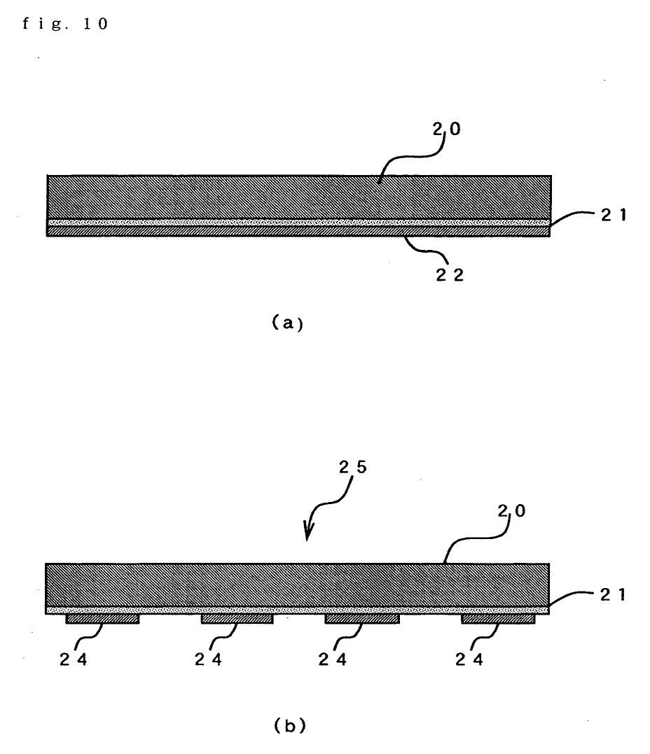

Wiring board having a usable specific shape: It is preferable for the wiring board having the pad electrode portion that its pad electrode portion is embedded in the base material of the wiring board and the surface of the pad electrode portion and the reference surface of the wiring board to be substantially equal in height. An example of such wiring board is shown in FIG. 7(A). By using such a wiring board 2′ and roughing the surface of the pad electrode portion 3 of this wiring board 2′, roughing shown in FIG. 7(B-1) or that shown in FIG. 7(B-2) is processed. After that, as shown in FIG. 8(C) (in the illustration in any of FIG. 8 below, the use of what is shown in FIG. 7(B-1) is supposed), the thermosetting adhesive resin layer 6 is provided over that roughened surface as the adhesive layer for connecting the pad electrode portion 3 of the wiring board 2 and the bump area 5 of the electronic component 4. Then, as shown in FIG. 8(D), the electronic component 4 is mounted over the surface of this thermosetting adhesive resin layer 6. After that, in order to re-fluidize and harden the thermosetting resin layer 6 in the semi-cured stage, it is stuck under heating and pressure to form the surface-packaged substrate 1 as shown in FIG. 9(E).

As a result, it is made possible to reduce the total thickness of the surface packaging substrate after the packaging of the electronic component over the wiring board. Embodiments of the invention will be described below.

### Embodiment 1

In this embodiment, a method by which flip chip components are surface-packaged over the surface of a four-layered printed wiring board is shown. It will be described below with reference to FIG. 1 and FIG. 2.

First, the wiring board 2 having the pad electrode portions 3 shown in FIG. 1(A) was made available. This wiring board 2, which is a so-called four-layered printed wiring board, is provided with inner-layer circuits and outer-layer circuits, and through holes and via holes needed as inter-layer communication paths between the inner-layer circuits and the outer-layer circuits are formed therein. On the outer layer of this wiring board 2, there are a plurality of (256) pad electrode portions 3 as part of outer-layer circuits. Each of these pad electrode portions has a copper plating layer (about 10 μm) over the surface of a 12-μm thick copper foil layer. In the electrolytic copper plating process to form the copper plating layer, a copper plating layer of 150 in Vickers' hardness (Hv) was formed by deposition.

By roughing the surface of these pad electrode portions 3 of the wiring board 2, the roughing illustrated in FIG. 1(B-1) was carried out. In this process, the copper surface was roughed by using a sulfuric acid-hydrogen peroxide micro-etching agent (MEC Etch Bond produced by MEC) to obtain a roughened surface of Rzjis=0.35 μm. After that, a nickel plating layer (about 5 μm) and a gold plating layer (1 μm) were successively formed over the roughed surface. These nickel plating layer and gold plating layer were formed by known substitutive type non-electrolytic nickel plating and non-electrolytic gold plating methods. The resultant thickness of the pad electrode portions was about 35 μm. The Vickers' hardness of the roughened surface after the successive formation of the nickel plating layer (about 5 μm) and the gold plating layer (1 μm) was 148 Hv.

After that, as shown in FIG. 2(C), the thermosetting adhesive resin layer 6 was provided over that roughened surface as the adhesive layer for connecting the pad electrode portion 3 of the wiring board 2 and the bump areas 5 of the electronic component 4. The resin used for this thermosetting adhesive resin layer was an epoxy resin composition with a 50% solid content, prepared by dissolving an 80 weight part of bromized bisphenol A type epoxy resin (YD-128, a product of Tohto Kasei Co., Ltd.), a 16 weight part of dimethyl formaldehyde solution having a 25% solid content (4 weight part as dicyandiamide) as the epoxy resin hardening agent and a 0.1 weight part of 2-ethyl 4-methylimidazole (Curezol 2E4MZ, a product of Shikoku Chemicals Corporation) as the hardening promoter in a mixed solvent of methyl ethyl ketone and dimethyl formaldehyde (mixed in a ratio of 4/6 between methyl ethyl ketone and dimethyl formaldehyde). The resin flow of this epoxy resin composition was measured to be 22%. The surface of the pad electrode portions 3 of the wiring board 2 was coated with this epoxy resin composition, and a certain quantity of the solvent was removed by being allowed to stand at room temperature for 30 minutes and exposing it to a warm air flow of 150° C. for two minutes with a hot air drier, resulting in drying to a semi-cured stage. The quantity of the epoxy resin composition coat was made 3 μm thicker in terms of dried resin thickness than the stub height of the pad electrode portions.

Next, as shown in FIG. 2(D), the electronic component 4 was mounted over the surface of the thermosetting adhesive resin layer 6 in this semi-cured stage. This electronic component was a so-called 256-pin flip chip having 256 bump areas, where the pitch of the electrodes was 120 μm, the size of the electrodes was 65 μm×65 μm, the electrode material was solder balls of 33 μm in diameter (lead-free solder composition), and its Vickers' hardness was 72 Hv. Therefore, the hardness difference between the bump areas and the stubs of the pad area was 76 Hv.

In order to re-fluidize and harden the thermosetting resin layer 6 in the semi-cured stage, it was stuck under heating and pressure as shown in FIG. 2(E) to form the surface-packaged substrate 1. The sticking condition used then was a variable load system (varying from the initial load of 5 g/bump to the final load of 30 g/bump) of applying ultrasonic wave during the joining process to increase the joining load stepwise. The applying conditions of ultrasonic wave were 3 μm in the oscillation amplitude of the chip energizing tool and 280 ms in the duration of ultrasonic wave application. As regards the joining temperatures, the tool heating temperature on the chip side was 230° C. and the temperature of the work stage on which to mount the substrate was room temperature.

In this way, 10000 flip chips were surface-packaged over the wiring board, and the defect rate was 0%, revealing a very satisfactory performance of surface packaging.

### Embodiment 2

In this embodiment, in place of the flip chips used in Embodiment 1, passivation layer-equipped flip chips, formed by providing a passivation layer over the electrode surface of each of those flip chips, were used. Since other aspects of the process are the same as their respective counter parts in Embodiment 1, their description will not be duplicated.

Therefore, the process of forming a passivation layer over the electrode surface of each of the flip chips and boring contact holes in it will be described with reference to FIG. 4 and FIG. 5. First, a usual flip chip component 10 was made available as shown in FIG. 4(A).

Then, as shown in FIG. 4(B), a passivation layer 11 was formed over the electrode surface of the flip chip component 10. This passivation layer was formed by let silane and ammonia (NH₃) flow in a reduced pressure CVD process, by which the pressure in the reactor was reduced with a vacuum pump to let the reactive gas flow, and so forming a silicon nitride film as to be 1 μm thicker than the bump area in the bump area (1 μm thick electrode of lead-free solder composition). Therefore, the average thickness of the passivation layer in the areas between bumps is 2 μm.

Next, as shown in FIG. 5(C), 65 μm×65 μm openings were formed in positions matching the bump areas 3 of the passivation layer 10. The formation of these openings used photolithography and irradiation with Ar+ ions to achieve sputter etching to expose the surface of the bump areas of the flip chips, resulting in the formation of the contact holes 12.

Then, the contact holes 12 formed as shown in FIG. 5(D) were filled with silver paste containing fine silver particles having an average primary grain size in the nm order by screen printing as the conductive substance 13. After that, the surfaces of the contact holes 11 were uniformly ground to obtain the passivation layer-equipped flip chip components 14 shown in FIG. 6(E).

Besides that, in the same way as in Embodiment 1, the passivation layer-equipped flip chip components 14 were packaged over the wiring board. As a result, 10000 flip chips were surface-packaged over the wiring board, and the defect rate was 0%, revealing a very satisfactory performance of surface packaging.

### Embodiment 3

In this embodiment, in place of the wiring board in Embodiment 1, a wiring board whose pad electrode portions were embedded in its base material and in which the surface of the pad electrode portion and the reference surface of the wiring board were substantially equal in height was used. Such a wiring board can be fabricated by first etching a copper foil layer with a half-hardened resin layer into a circuit shape and subjecting it to stack pressing by heating the inner layer core material, prepreg and the like to embed within the half-hardened resin layer the circuit formed by etching. However, the wiring board used here was fabricated by using a copper foil having a carrier foil as described below.

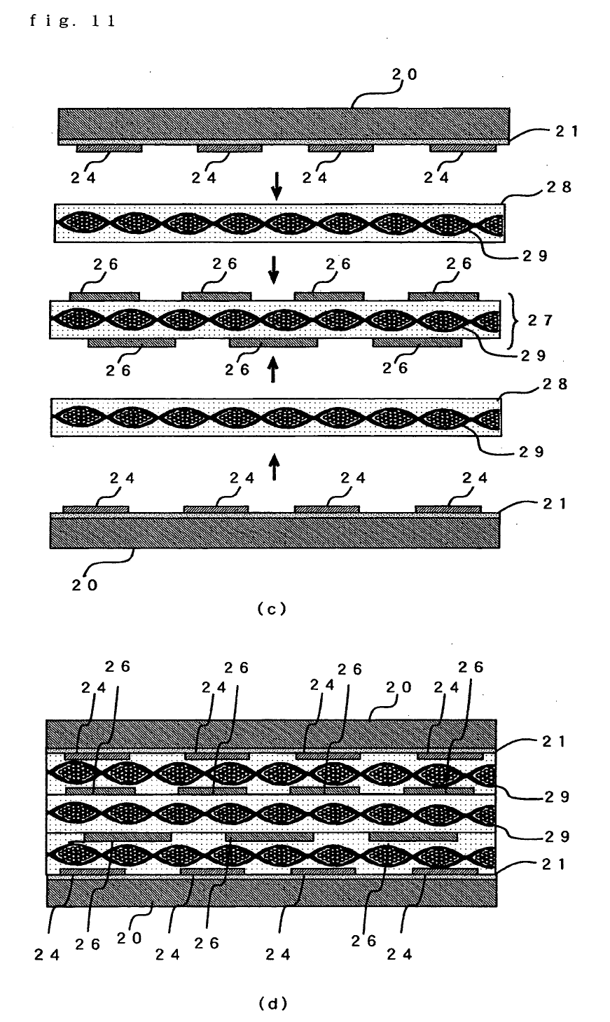

For this embodiment, first there was prepared a carrier foil-equipped electrolytic copper foil 23 having a release layer 21 mainly consisting of nickel on one surface of a carrier copper foil 20 of 35 μm in thickness as shown in FIG. 10(A) and an electrolytic copper foil layer 22 of 3 μm in thickness provided over that release layer 21. Then, by using a dry film, a resist pattern for use in etching was formed on the surface of that electrolytic copper foil layer 22 by exposure to light and development. To prevent subsequent damage by an etching liquid, an etching resist layer was also formed all over the surface on the carrier foil 20 side. After that, the electrolytic copper foil layer 22 was etched with a copper etching liquid to form a circuit pattern 24, and the etching resist layer was wetted and removed with an alkali solution to obtain a circuit patterned carrier foil 25 as shown in FIG. 10(B).

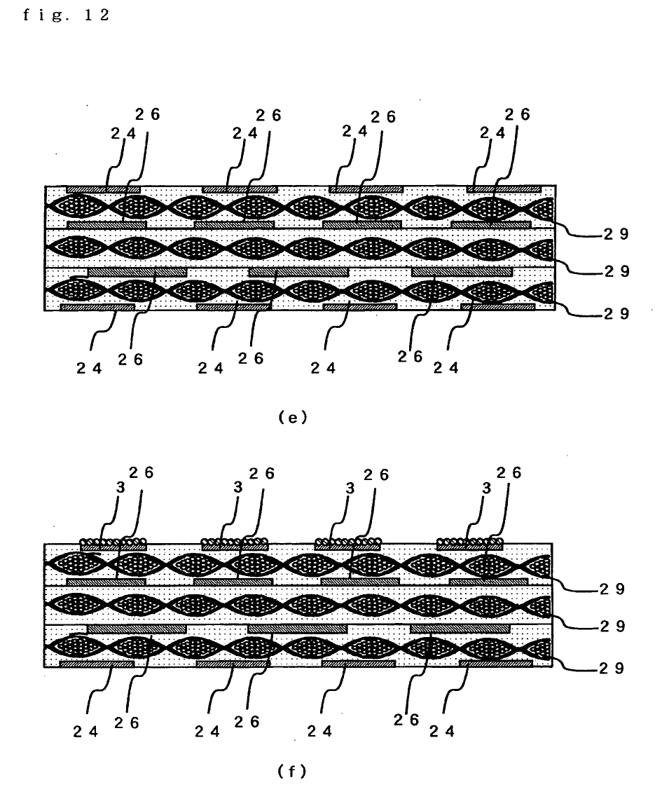

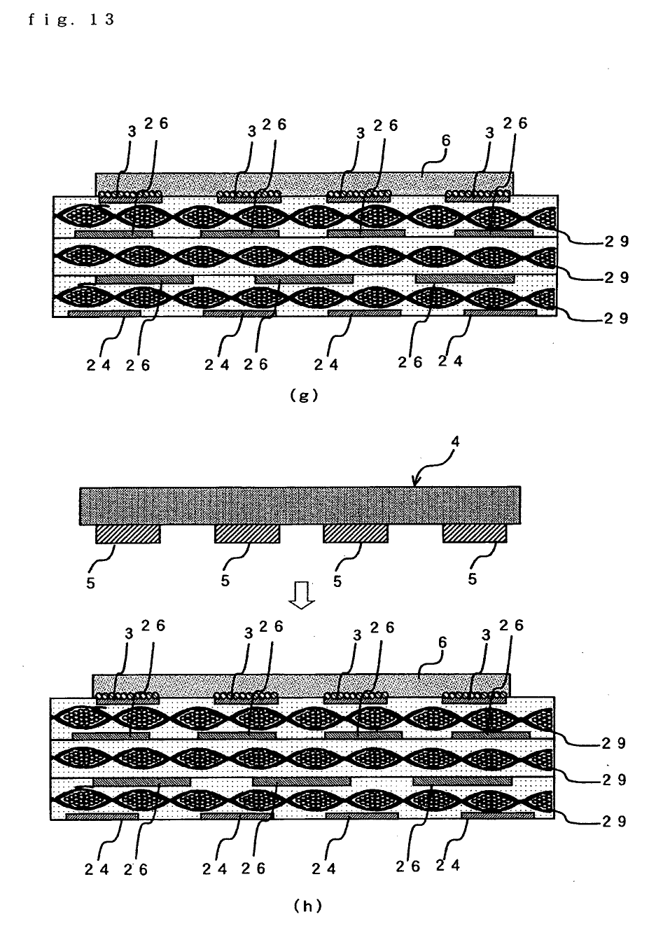

Then, as shown in FIG. 11(C), an FR-4 base material (containing glass cloth as a skeletal material 29) of 120 μm in thickness was arranged as an insulating layer constituent material 28 on each surface of an inner-layer core material 27 provided with an inner-layer circuit 26, and further the circuit patterned carrier foil 25 was arranged and subject to hot pressing according to its prescribed formula to achieve the state shown in FIG. 11(D). After that, the pad electrode portion 3 shown in FIG. 12(E) was embedded within the base material of the wiring board 2 by peeling off the carrier copper foil, and the surface of the pad electrode portion 3 and the reference surface of the wiring board 2 were substantially equalized in height. Then, necessary through holes and via holes were formed (their illustration is in the drawings). On the outer layer of this wiring board 2, there are a plurality of (256) pad electrode portions 3 as part of outer-layer circuits. Each of these pad electrode portions has a copper plating layer (about 10 μm) over the surface of a 12-μm thick copper foil layer. In the electrolytic copper plating process to form the copper plating layer, a copper plating layer of 150 in Vickers' hardness (Hv) was formed by deposition.

Further, an etching resist layer was formed elsewhere than the pad electrode portions, and fine nickel particles of 2 μm in average grain size were deposited on and stuck to the surface of the pad electrode portion by electrolysis to achieve the state shown in FIG. 12(F). Then, after the successive formation of gold plating layers (1 μm) in the same way as in Embodiment 1, the Vickers' hardness of the roughened surface was 165 Hv.

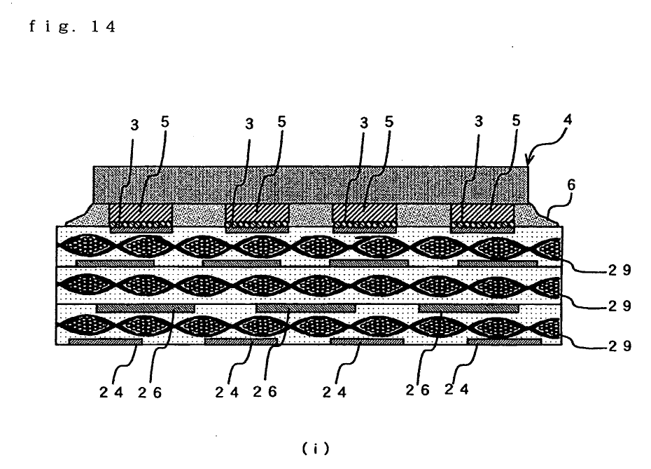

After that, as shown in FIG. 13(G), the thermosetting adhesive resin layer 6 was provided over that roughened surface as the adhesive layer for connecting the pad electrode portion 3 of the wiring board 2 and the bump areas 5 of the electronic component 4 as in Embodiment 1, and dried to a semi-cured stage.

Next, as shown in FIG. 13(H), the electronic component 4 was mounted over the surface of the thermosetting adhesive resin layer 6 in this semi-cured stage. This electronic component is the same as its counter part in Embodiment 1, and the joining method also used the same conditions as in Embodiment 1. As a result, the surface-packaged substrate 1 shown in FIG. 14(I) was obtained.

In this way, 10000 flip chips were surface-packaged over the wiring board, and the defect rate was 0%, revealing a very satisfactory performance of surface packaging.

By using the packaging method according to the invention for electronic components, electronic components having bump areas and a wiring board having a pad electrode portion can be connected with remarkable ease to each other with secure electrical conduction, and the defect rate in the packaging process is significantly reduced. Therefore, the quality of the surface-packaged substrate is further improved. Furthermore, the process of production can use the conventional packaging line, plating line and etching line, and no particular capital investment would be newly required, making possible effective utilization of existing facilities.

What is claimed is:

1. A packaging method for connecting electronic components having bump areas and a wiring board having a pad electrode portion while securing electrical conduction between them, wherein;
the surface of said pad electrode portion of the wiring board is provided with a roughened surface of 0.1 μm (Rzjis) or more, comprising the steps of:
providing a layer of thermosetting adhesive resin in a semi-cured stage over the roughened surface of the pad electrode portion;
placing the bump areas of said electronic components and the pad electrode portion of the wiring board one over the other to be arranged opposite to each other, and
crimping under pressure and heating the bump areas of said electronic components and the pad electrode portion of the wiring board.

2. The packaging method for electronic components according to claim 1, wherein the roughened surface of said pad electrode portion of the wiring board is obtained by etching pad electrodes.

3. The packaging method for electronic components according to claim 1, wherein the roughened surface of said pad electrode portion of the wiring board has a prominent shape electrodeposited by an electro plating or a electro-less plating.

4. The packaging method for electronic components according to claim 1, wherein the difference in Vickers' hardness between the metal component constituting said bump areas of electronic components and the metal component constituting said pad electrode portion of the wiring board is 15 Hv or more.

5. The packaging method for electronic components according to claim 1, wherein said electronic components are flip chip components.

6. The packaging method for electronic components according to claim 5, wherein each of the flip chip component is a flip chip component with a passivation layer on its electrode surface which has a contact hole opened only in the position matching a bump area and the contact hole is filled with a conductive material.

7. The packaging method for electronic components according to claim 1, wherein said electronic component is a wiring board having bump areas.

8. The packaging method for electronic components according to claim 7, wherein the wiring board having a pad electrode portion is a wiring board whose pad electrode portion is embedded in the base material of the wiring board and in which level of the pad electrode portion surface is substantially even with the reference surface of the wiring board.

9. The packaging method for electronic components according to claim 1, wherein the material of said layer of thermosetting adhesive resin is constituted with at least one resin material selected from epoxy functional thermosetting resin, phenol functional thermosetting resin, polyimide functional thermosetting resin or urethane functional thermosetting resin.

10. The packaging method for electronic components according to claim 1, wherein said layer of thermosetting adhesive resin contains anisotropic conductive particles.

11. The packaging method for electronic components according to claim 9, wherein the resin flow of said layer of thermosetting adhesive resin is 15% to 50%.
